(19) United States
(12) Patent Application Publication
(10) Pub. No.: US 2021/0044221 A1
(43) Pub. Date: Feb. 11, 2021

(54) Energy Harvester for Harvesting Energy from Broadband Ambient Vibrations

(71) Applicant: 8POWER LIMITED, Cambridge, Cambridgeshire (GB)

(72) Inventors: Yu JIA, Chester, Cheshire (GB); Ashwin Arunkumar Seshia, Cambridge, Cambridgeshire (GB); Jize Yan, Eastleigh, Hampshire (GB); Maryam Ghandchi Tehrani, Southampton, Hampshire (GB)

(21) Appl. No.: 17/044,722

(22) PCT Filed: Apr. 1, 2019
(86) PCT No.: PCT/GB2019/050945

§ 371 Date: Oct. 1, 2020

(30) Foreign Application Priority Data
Apr. 3, 2018 (GB) 1805468.4

(51) Int. Cl. H02N 2/18

(52) U.S. Cl. CPC H02N 2/188

(57) ABSTRACT

There is provided an energy harvester for harvesting energy from broadband ambient vibrations comprising: a bi-stable oscillator, a subsidiary oscillator mechanically coupled to the bi-stable oscillator; wherein the bi-stable oscillator has a snap through frequency, ωₛₙₐₚ, as a result of the ambient vibrations, and wherein the subsidiary oscillator exhibits resonance when driven at a frequency of ωₛₙₐₚ; and at least one transducer coupled either to the bi-stable oscillator or to the subsidiary oscillator. This arrangement allows for resonant vibrational energy harvesting for be achieved over a broadband of input vibration frequencies.

### FIELD OF THE INVENTION

The invention relates to an energy-harvesting apparatus and method, for harvesting or collecting energy from broadband ambient vibrations.

### BACKGROUND TO THE INVENTION

Vibration energy harvesting (VEH) converts ambient kinetic energy into useful electrical energy. VEH is particularly useful in civil, transport and industrial applications where conventional power sources, such as mains supply or batteries, are either impractical or costly to maintain and alternative power sources, such as solar, are not feasible.

A fundamental problem with VEH is the confined nature of the operational frequency bandwidth in typical VEH devices. Many of the real world vibrations that would be desirable to harvest are broadband, noisy and varying in nature and so cannot be efficiently harvested by a single VEH device.

There have been several mechanisms developed to maximise the amount of recoverable energy from broadband vibration sources, however all the mechanisms to date have only a modest response frequency bandwidth.

It would be desirable to harvest energy from broadband ambient vibrations and deliver both resonant amplification and broadband response.

### SUMMARY OF THE INVENTION

The invention provides an energy harvester and method for harvesting energy from broadband ambient vibrations, as defined in the appended independent claims, to which reference should now be made. Preferred or advantageous features of the invention are set out in dependent sub-claims.

In a first aspect there is provided an energy harvester for harvesting energy from broadband ambient vibrations comprising:

a bi-stable oscillator,

a subsidiary oscillator mechanically coupled to the bi-stable oscillator;

wherein the bi-stable oscillator has a snap through frequency, ωₛₙₐₚ, as a result of the ambient vibrations, and wherein the subsidiary oscillator exhibits resonance when driven at a frequency of ωₛₙₐₚ; and

at least one transducer coupled either to the bi-stable oscillator or to the subsidiary oscillator.

As explained in detail below, the configuration of the subsidiary oscillator coupled to the bi-stable oscillator enables a resonant response to a broadband input, which is amplitude dependent. The subsidiary oscillator may be driven in parametric resonance or direct resonance by the bi-stable oscillator, dependent on a relationship between a resonant frequency of the subsidiary oscillator and a frequency of intra-potential well hopping in the bi-stable oscillator. To harvest energy from the resonant amplification, the subsidiary oscillator is damped. The bi-stable oscillator can either be damped or not damped. The oscillators of the energy harvester are designed based on knowledge of the expected average or typical amplitude of vibration that will be experienced by the energy harvester in the particular intended setting or environment.

In this context “exhibits resonance” means that the response amplitude of the subsidiary oscillator is greater than the driving amplitude of the bi-stable oscillator. Response amplitude in this context may be an amplitude of displacement, velocity or acceleration.

In this context, a bi-stable oscillator is an oscillator with more than one stable equilibrium position, each stable equilibrium position separated from an adjacent stable equilibrium position by unstable positions. In terms of potential energy, a bi-stable oscillator has at least two local minima of potential energy separated by a potential barrier. However, a bi-stable oscillator may have more than two local minima of potential energy and so may be multi-stable. The oscillator has multiple intra-system potential wells, each potential well associated with a stable equilibrium position. The bi-stable oscillator may comprise a resilient beam that flexes or deforms during oscillation. There are a number of ways in which an oscillator of this type can be configured to be bi-stable. In one example, the beam may be a clamped-clamped beam that is pre-stressed so that the beam is in a lower potential energy state when the beam is curved rather than straight. Alternatively, magnetic or electrostatic fields may be used to induce bi-stability.

Energy can be harvested from normal oscillatory or resonant behaviour within any of the potential wells associated with a stable equilibrium position. The instantaneous energy release when the bi-stable system hops from one equilibrium position to another across the potential barrier between the two equilibrium positions may also be harvested.

This intra-well hopping is also known as snap-through. The vibration required to induce snap-through is generally independent of the frequency of the vibration and only requires the vibration amplitude to be large enough to cause the oscillator to cross the potential barrier. The frequency of snap through is related to the amplitude of the vibration, so that the greater the amplitude of vibration, the higher the rate of snap-through.

If the broadband ambient vibrations are of predictable average amplitude, then the snap-through rate can be predicted. The frequency make-up of the vibrations, which is typically less predictable and broadband, is not significant. Therefore, assuming sufficient amplitude, the bi-stable snap-through mechanism is responsive across a wide range of frequencies. The energy harvester may be especially effective with low frequency vibrations where displacement amplitude is high.

In order to more efficiently harvest vibration energy, resonant amplification of the subsidiary oscillator is exploited. By matching a resonant frequency of the subsidiary oscillator to the expected snap-through rate of the bi-stable oscillator, the subsidiary oscillator can be driven to resonate. The response of the bi-stable oscillator to external excitations serves as the excitation for the subsidiary oscillator. In this way resonant amplification of the broadband ambient vibrations is achieved.

Systems that rely on resonance typically have a disadvantage that the operational range is bound by a particular bandwidth within which a resonant response occurs. The snap-through action of a bi-stable oscillator is inherently non-resonant and so does not benefit from resonant amplification. However combining the nonlinear vibration dynamics of the subsidiary oscillator and a snap-through operation of the bi-stable oscillator results in an inherently broadband system, which provides a resonant response over a wide range of frequencies. The activation of resonance for this system is amplitude dependent, and the required amplitude for at least one snap-through state is constant over a broad band of excitation frequencies.

It is possible to achieve resonant amplification of the broadband ambient vibrations even when the amplitude of the vibration is insufficient on its own to activate snap-through of the bi-stable oscillator owing to a phenomenon called stochastic resonance.

Stochastic resonance is a vibrational phenomenon where a periodic excitation which is usually too small to yield a meaningful result to detect, becomes meaningful with the addition of white noise. The addition of white noise helps to boost the signal-to-noise ratio. In this context the ambient vibrations may comprise a periodic component and noisy vibrations. This is very common in real-world systems. The periodic excitation may have insufficient amplitude to give rise to snap-though of the bi-stable oscillator. And the noisy vibrations may have insufficient amplitude to give rise to snap-though of the bi-stable oscillator. But together they may give rise to snap-though as a result of stochastic resonance.

Stochastic resonance can be achieved when the frequency of the periodic vibration is near to half of the Kramer's rate (KR) of the bi-stable oscillator, where Kramer's rate describes the probability of intra-potential well hopping, also known as the snap-through rate. This is described by the following equations:

$$\begin{matrix}U ( x , t ) = - \frac{1}{2} b {x}^{2} + \frac{1}{4} d {x}^{4} - a x c o s ( ω t ) & ( 1 ) \\ {ω}_{K R} = 2 \frac{b}{\sqrt{2}} exp ( - \frac{Δ U}{D} ) = 2 \frac{b}{\sqrt{2}} exp ( - \frac{{b}^{2}}{4 d D} ) & ( 2 )\end{matrix}$$

where U is the potential energy, ΔU is a potential barrier in a bi-stable system, b and dare parameters that describe the bi-stable potential wells, ω_{KR} is the Kramer's rate for a bi-stable oscillator, and D is noise intensity. The parameter b relates to the negative spring stiffness of the bi-stable oscillator and the parameter d is a cubic nonlinearity coefficient (Duffing coefficient). For example where bi-stability is induced by introducing a magnetic spring, the response of the oscillator is determined by the magnetic field strength, the distance between the magnets and resulting nonlinearity in the stiffness. In that case, b relates to the repulsive magnetic field strength resulting in the negative spring restoring force causing the bistability, and d is the strength of the cubic stiffness nonlinearity of the magnetic spring.

If D is much smaller than the potential barrier ΔU, in absence of the periodic modulation of the potential barrier, snap-through cannot occur. With the introduction of a weak periodic excitation a(t), modulation of the potential barrier occurs and promotes the chance of system hopping between the potential intra-wells.

Stochastic resonance can be achieved when the average statistical frequency of snap-through ωₛₙₐₚ is around twice that of the periodic excitation ω. That is, ωₛₙₐₚ≈ω_{KR}≈2ω. The ideal frequency for stochastic resonance is given by:

$$ω = \frac{1}{2} {ω}_{K R} = \frac{b}{\sqrt{2}} exp ( - \frac{{b}^{2}}{4 d D} ) \qquad ( 3 )$$

Stochastic resonance can be achieved for a given range of D based on equation 3. Preferably, the energy harvester is designed so that the frequency of the periodic excitation ω is close to the ideal value given in equation 3. The frequency of the periodic excitation ω may be between 0.6 and 1.4 times the ideal value given in equation 3. However, for stochastic resonance, ω is not greater than b/√2.

In many vibrating environments there are one or more periodic vibrations that are typically present as well as vibratory noise. For example, on a motor there may a periodic vibration at the typical operating frequency of the motor as well noisy vibrations of a substantially constant amplitude. By careful design of the energy harvester, based on knowledge of the expected noise intensity and a periodic vibration frequency, it is possible to exploit stochastic resonance of the bi-stable oscillator in such environments.

The subsidiary oscillator may be arranged to be driven in parametric resonance or direct resonance by the bi-stable oscillator.

In some embodiments, the subsidiary oscillator of the energy harvester may be arranged to be driven in direct resonance by oscillation of the bi-stable oscillator. In these embodiments, ωₛₙₐₚ is substantially equal to ω₀, where ω₀ is a resonant frequency of the subsidiary oscillator. However, ωₛₙₐₚ need not be exactly equal to ω₀ as there is a band of frequencies over which the subsidiary oscillator will exhibit resonance. The subsidiary oscillator may be configured so that the Q factor of the subsidiary oscillator is matched to variance of the snap-through rate of the bi-stable oscillator. For subsidiary oscillators with low Q, there may be a relatively broad band of snap-through rate at which the subsidiary oscillator resonates. Preferably, when the subsidiary oscillator is arranged to be driven in direct resonance, 0.6ω₀<ωₛₙₐₚ<1.4ω₀. More preferably, 0.8ω₀<ωₛₙₐₚ<1.2ω₀.

Alternatively, the subsidiary oscillator of the energy harvester may be arranged to be driven in parametric resonance by oscillation of the bi-stable oscillator. In that case ωₛₙₐₚ is substantially equal to 2 ω₀/n, where ω₀ is a resonant frequency of the subsidiary oscillator and n is a positive integer. Again, preferably 0.6ω₀<nωₛₙₐₚ/2<1.4ω₀, and more preferably, 0.8ω₀<nωₛₙₐₚ/2<1.2ω₀. Even more preferably, 0.9ω₀<nωₛₙₐₚ/2<1.1ω₀.

Parametric resonance arises from driving forces that induce a periodic variation in at least one of the system parameters. The subsidiary oscillator may be driven in auto-parametric resonance.

Where the subsidiary oscillator is arranged to be driven in parametric resonance, the subsidiary oscillator may be arranged to oscillate in a direction orthogonal to a direction of oscillation of the bi-stable oscillator.

An advantage of using parametric resonance in an energy harvesting system is that it can provide a more efficient conversion of vibration energy into electrical energy compared to direct resonance.

Alternatively, the primary bi-stable oscillator may be internally coupled to both a direct oscillator and a parametric oscillator, gaining the advantages of both resonant regimes.

The energy harvester may comprise a frame to which the bi-stable oscillator is coupled. The frame may be fixed to a vibrating structure by a fixing device, such as one or more screws or bolts.

A magnetic field may be used to induce bi-stability in the bi-stable oscillator. For example the bi-stable oscillator may comprise a resilient cantilever flexure fixed to the frame, and two opposed magnets, a first magnet fixed to a free end of the cantilever flexure and second magnet, magnetically opposed to the first magnet, fixed to the frame adjacent to the free end of the cantilever flexure at a zero displacement position of the flexure. The two opposed magnets create an unstable equilibrium at the zero displacement position and two stable positions on opposite sides of the zero displacement position in which the mechanical restoring forces resulting from deformation of the flexure are equal to the magnetic repulsion force between the opposed magnets.

Alternatively, the bi-stable oscillator may comprise a membrane flexure. The membrane flexure may comprise a clamped-clamped resilient beam, fixed at both ends to the frame. The clamped-clamped beam may have a length greater than a distance between the two fixed ends of the beams. In this configuration clamped-clamped beam is bi-stable, having stable equilibria in two opposed buckled states. Other forms of membrane, such as a disc, which are fixed to the frame at a plurality of positions may be configured to achieve the same effect.

An advantage of using a membrane is that it provides a broad frequency band over which vibrational energy can be harvested efficiently.

As an alternative, or in addition to using magnets or mechanical stress, the bi-stable oscillator may be pre-stressed in other ways, such as thermal stress or residual stress, or by using electrostatic fields. The flexure may be formed from a suitable resilient material, such as spring steel.

The subsidiary oscillator may comprise a proof mass attached to a resilient flexure. The bi-stable oscillator may also comprise a proof mass. By adjusting the magnitude of the proof mass or proof masses, the energy harvester can be tuned to provide a desired response.

The energy harvester may comprise a plurality of subsidiary oscillators mechanically coupled to the bi-stable oscillator. Using a plurality of subsidiary oscillators may generate a larger power output than using only one subsidiary oscillator.

Some or all of the bi-stable and subsidiary oscillators may comprise a pair of flexures spaced apart in a direction of intended vibration of the oscillator. The pair of flexures may both be fixed to the same proof mass and to the frame. The pair of flexures may be coupled by spacer elements. The use of two, or more, flexures spaced in this way increases the torsional stiffness of the oscillator and so reduces the likelihood of torsional modes of vibration being excited by the ambient vibrations.

The at least one transducer may comprise an electromagnetic transducer, an electrostatic transducer, an electret transducer, a triboelectric transducer or a piezoelectric transducer, for example. Any combination of these transduction technologies may be used. In one embodiment, a piezoelectric element is deposited on the subsidiary oscillator. In another example, a coil is fixed to the subsidiary oscillator and moves within a static magnetic field as the subsidiary oscillator resonates.

A second transducer may be coupled to the bi-stable oscillator. This may be used to extract power directly from the bi-stable oscillator, particularly during periods when ambient vibrations are insufficient to achieve a snap-through rate for which the energy harvester has been designed.

The at least one transducer may comprise one or more of an electromagnetic transducer, an electrostatic transducer, an electret transducer, a triboelectric transducer or a piezoelectric transducer. The at least one transducer may comprise an electrical output. The electrical output may be connected to a battery or other energy storage device. Signal conditioning circuitry may be provided between the electrical output and the energy storage device.

In one embodiment, the bi-stable oscillator comprises a resilient flexure having a length in a first direction, a width in a second direction and a thickness in a third direction, the thickness being less than the width and the length, wherein the subsidiary oscillator comprises a resilient flexure having a length extending in the second direction, and width extending in the first direction and a thickness extending in the third direction, the thickness being less than the width and the length. In this embodiment, the subsidiary oscillator may be configured to be driven in direct resonance by the bi-stable oscillator.

In another embodiment, the bi-stable oscillator comprises a resilient flexure having a length in a first direction, a width in a second direction and a thickness in a third direction, the thickness being less than the width and the length, wherein the subsidiary oscillator comprises a resilient flexure having a length extending in the third direction, and width extending in the first or second direction and a thickness extending in the first or second direction, the thickness being less than the width and the length. In this embodiment, the subsidiary oscillator may be configured to be driven in parametric resonance by the bi-stable oscillator

In a further aspect of the invention, there is provided a method for harvesting energy from ambient vibrations using broadband resonance of a vibration energy harvester comprising a bi-stable oscillator mechanically coupled to a subsidiary oscillator, the method comprising:

exposing the bi-stable oscillator to ambient vibrations in order to excite the bi-stable oscillator with a snap through frequency, ωₛₙₐₚ, such that ωₛₙₐₚ is related to a resonant frequency of the bi-stable oscillator so that the subsidiary oscillator exhibits resonance when driven at a frequency of ωₛₙₐₚ; and

extracting a power output by damping the subsidiary oscillator, or damping both the bi-stable oscillator and the subsidiary oscillator.

The method of harvesting energy advantageously converts kinetic energy through resonant means, into useful electrical energy, even when the ambient vibration is broadband and stochastic in nature. The response of the bi-stable oscillator to ambient vibration serves to drive the subsidiary oscillator in a non-linear resonance mode. A power output can therefore be extracted from the subsidiary oscillator. Power output is extracted by a damping process.

The bi-stable oscillator is excited by ambient vibrations and may drive the subsidiary oscillator in direct resonance, wherein the direct oscillator resonates at a frequency substantially equal to ωₛₙₐₚ of the bi-stable oscillator.

Alternatively, the bi-stable oscillator may be excited by ambient vibrations to drive the subsidiary oscillator in parametric resonance. Parametric resonance of the subsidiary oscillator occurs when ωₛₙₐₚ of the bi-stable oscillator is substantially equal to 2 ω₀/n, where ω₀ is a resonant frequency of the subsidiary oscillator and n is a positive integer.

The ambient vibrations may include at least one periodic vibration in combination with a broadband vibration. The method may then exploit stochastic resonance. When the bi-stable oscillator is driven in stochastic resonance, direct resonance of the subsidiary oscillator peaks when the snap-through frequency of the bi-stable oscillator is close to twice the frequency of the periodic vibration.

The damping of the subsidiary oscillator may be achieved using electromagnetic, electrostatic, electret, triboelectric or piezoelectric transduction.

In a further aspect of the invention, there is provided an oscillatory system driven by broadband mechanical vibrations having an expected amplitude, comprising:

a bi-stable oscillator,

a subsidiary oscillator mechanically coupled to the bi-stable oscillator; wherein the bi-stable oscillator has a snap through frequency, ωₛₙₐₚ, as a result of the broadband mechanical vibrations having the expected amplitude, and wherein the subsidiary oscillator resonates when driven at a frequency of ωₛₙₐₚ.

An oscillatory system in accordance with this aspect of the invention may be used as part of a sensor, transducer or oscillator. Features described in relation to the one aspect of the invention may be applied to this other aspects of the invention. In particular, the subsidiary oscillator of the further aspect may be configured to be driven in direct or parametric resonance. There may also be a plurality of subsidiary oscillators coupled to the bi-stable oscillator.

### BRIEF DESCRIPTION OF THE DRAWINGS

Embodiments of the invention are described in detail, by way of example only, with reference to the accompanying drawings, in which:

FIG. 1A is a block diagram showing the elements of a vibration energy harvester in accordance with the invention;

FIG. 1B illustrates the potential energy stored in a bi-stable oscillator versus displacement;

FIG. 2 is a schematic diagram of a first embodiment of a vibration energy harvester in accordance with the invention;

FIG. 3 is a schematic diagram of a second embodiment of a vibration energy harvester in accordance with the invention;

FIG. 4A is a schematic diagram of a third embodiment of a vibration energy harvester in accordance with the invention;

FIG. 4B is a side view of the embodiment of FIG. 4A:

FIG. 4C is a top view of the embodiment shown in FIG. 4A;

FIG. 5A is a schematic diagram of a fourth embodiment of a vibration energy harvester in accordance with the invention;

FIG. 5B is a side view of the embodiment shown in FIG. 5A;

FIG. 5C is a top view of the embodiment shown in FIG. 5A;

FIG. 6A is a schematic diagram of a fifth embodiment of a vibration energy harvester in accordance with the invention;

FIG. 6B is a side view of the embodiment shown in FIG. 6A;

FIG. 6C is a top view of the embodiment shown in FIG. 6A;

FIG. 7A is a schematic diagram of a sixth embodiment of a vibration energy harvester in accordance with the invention; and

FIG. 7B is a side view of the embodiment shown in FIG. 7A.

### DETAILED DESCRIPTION

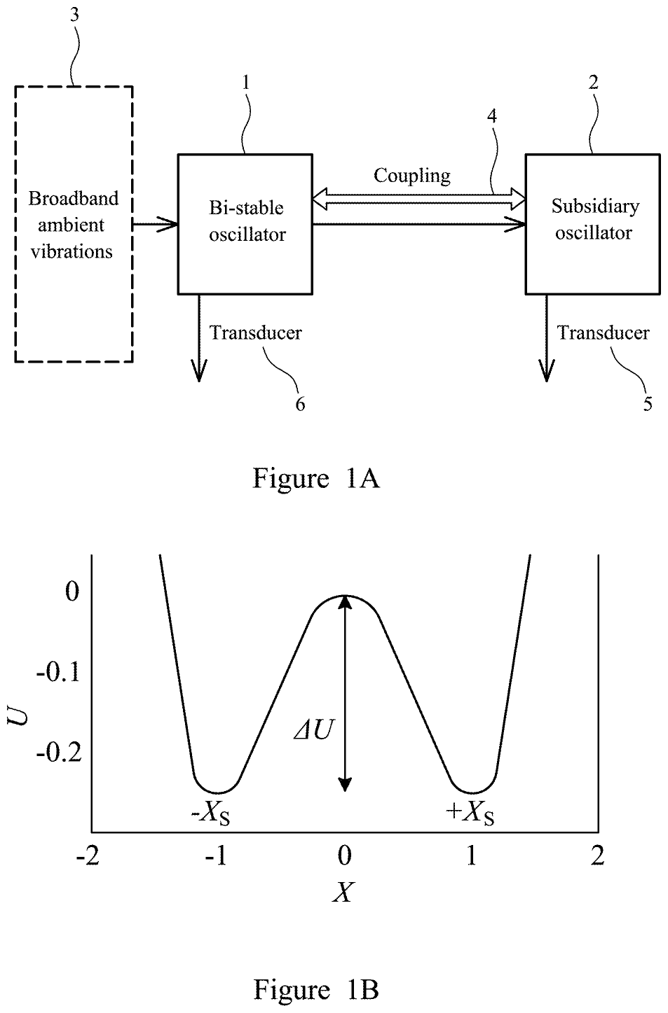

FIG. 1A is a block diagram of a vibration energy harvester (VEH) in accordance with the invention. The VEH comprises a bi-stable oscillator 1 coupled to a subsidiary oscillator 2 by a mechanical coupling 4. The VEH is placed in an environment in which vibration energy can be harvested. Ambient broadband vibrations 3 cause the bi-stable oscillator to vibrate. Vibration of the bi-stable oscillator drives the subsidiary oscillator to vibrate. Energy is harvested from the subsidiary oscillator using a kinetic-to-electric transducer 5. A second kinetic-to-electric transducer 6 may be used to extract energy from the bi-stable oscillator in some circumstances as well.

FIG. 1B illustrates the two potential energy wells of a bi-stable oscillator as function of displacement of the oscillator. It can be seen that there is an unstable equilibrium at a zero displacement position, with lower potential energy states on either side of the zero displacement position. So if the bi-stable oscillator starts in a stable equilibrium position at a displacement of 1 and is driven by an input vibration it may respond in a number of ways.

If the input vibration has sufficient energy it may push the bi-stable oscillator over the potential barrier between the two potential wells to the other stable equilibrium position. This is called snap-through or intra-well hopping. If the ambient vibration continuously has a sufficient amplitude, the bi-stable oscillator will snap-through from one stable equilibrium position to the other. The rate of snap-through, also referred to as the snap-through rate, depends on the displacement amplitude of the input vibration. The frequency of the input vibration in this context is irrelevant.

If the input vibration does not have sufficient energy to clear the potential barrier, the bi-stable oscillator will vibrate within the potential well in which it started. If the input vibration has a frequency that matches a resonant frequency of the bi-stable oscillator, then the bi-stable oscillator may resonate within the potential well, building up energy within one potential well until it has sufficient energy to achieve snap-through.

There is also the possibility of achieving snap-through by a phenomenon called stochastic resonance. Stochastic resonance can be explained by considering a typical bi-stable system (for example FIG. 1B) experiencing a periodic forcing that is less than sufficient to cross the potential barrier. Although the system is trapped in a potential intra-well, when driven into resonance, it can still yield a meaningful power output. However, with the addition of noise (stochastic excitation) into the system, the extra energy in combination with the periodic forcing could activate snap-through. The frequency spectrum of the noise is irrelevant.

Snap-through from one stable state to the other provides a large instantaneous energy release. Because the rate of snap-through is dependent on the amplitude of the forcing vibration it can be used to harvest energy over a broad band of vibration frequencies.

The bi-stable oscillator is mechanically coupled to a subsidiary oscillator. When the bi-stable oscillator is subjected to external vibrations, the response of the bi-stable oscillator in turn drives the subsidiary oscillator. If the snap-through rate of the bi-stable oscillator is matched to a resonant frequency of the subsidiary oscillator, the subsidiary oscillator can be driven in resonance and damped by a transducer 5 to extract energy. The average amplitude of ambient vibrations in a given environment is very often quite predictable, even when the frequency distribution of the vibrations is across a broad band and is random in nature. So by designing the VEH to achieve a snap-through rate when driven by the expected ambient vibrations that matches a resonant frequency of the subsidiary oscillator, the subsidiary oscillator can be made to resonate. Resonant amplification of the broadband input vibrations in this way allows for efficient energy harvesting and significant output voltages to be obtained.

Depending on the design of the VEH, the subsidiary oscillator can be driven into direct resonance or into parametric resonance. The VEH may include a plurality of subsidiary oscillators, some of which are configured to directly resonate and others of which are configured to parametrically resonate.

Direct resonance of the subsidiary oscillator has the advantage that a relatively inexact match between the snap-through rate and the resonant frequency of the subsidiary oscillator is needed to achieve resonant amplification, particularly if the subsidiary oscillator is designed with a low Q value. In order for the subsidiary oscillator to directly resonate, the snap-through rate must be close to or equal to the resonant frequency of the subsidiary oscillator, and the snap-through of bi-stable oscillator should be in the same direction as the vibration of the parametric resonator.

Parametric resonance has the advantage of potentially providing for greater power output, but typically requires more exact frequency matching. For parametric resonance, the snap-through rate of the bi-stable oscillator needs to be substantially equal to 2 ω₀/n, where ω₀ is a resonant frequency of the subsidiary oscillator and n is a positive integer. In addition, the driving force resulting from the snap-through of the bi-stable oscillator must introduce a periodic variation in at least one of the system parameters of the subsidiary oscillator. Typically, although not always, as described in the examples below, where the subsidiary oscillator is arranged to be driven in parametric resonance, the subsidiary oscillator is arranged to oscillate in a direction orthogonal to a direction of oscillation of the bi-stable oscillator.

The system illustrated in FIG. 1A can also be designed to exploit stochastic resonance, as described above. If the ambient vibrations are known to include a periodic vibration of frequency ω as well as noise, then to exploit stochastic resonance, the bi-stable oscillator can be designed with an ω_{KR}≈2ω.

Various embodiments of the invention will now be described.

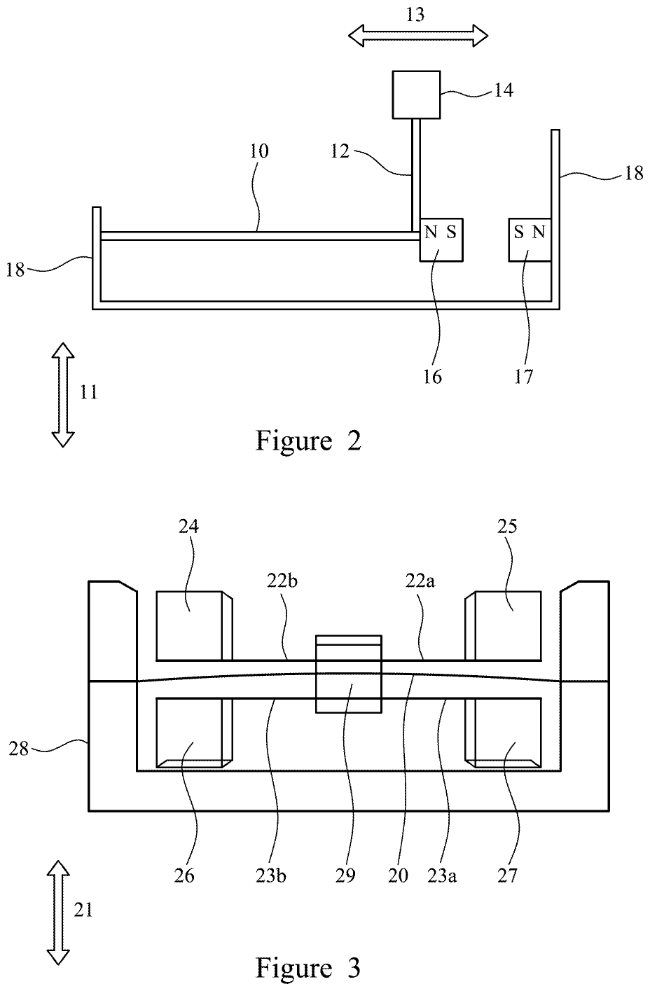

FIG. 2 is a schematic illustration of a VEH comprising a primary oscillator. The primary oscillator comprises a first resilient cantilever flexure 10 attached at its fixed end to a frame 18. In order to make the primary oscillator bi-stable, a first permanent magnet 16 is attached to the first cantilever flexure 10 and a second permanent magnet 17 is attached to the frame. The first and second permanent magnets are arranged with opposing poles so that they repel one another. The repelling magnetic dipoles establish an unstable equilibrium at a zero-displacement position, thereby inducing bi-stability.

A subsidiary oscillator is coupled to the primary oscillator, and comprises a second resilient cantilever flexure 12 extending orthogonal to the first flexure 10. The subsidiary oscillator comprises a proof mass 14 at the free end of the second cantilever flexure 12. A transducer, not shown, is used to damp the second cantilever flexure in order to harvest energy.

Under vibrational excitation in a first direction, indicated by arrow 11, the primary oscillator vibrates in the first direction. The movement of the free end of the first cantilever flexure 10 drives the second cantilever flexure 12. The second cantilever flexure 12 is arranged relative to the first cantilever flexure to be driven in parametric resonance. The subsidiary oscillator 12 is driven to vibrate in a second direction 13, which is orthogonal to the first direction. In this example, the second direction is parallel with the length of the primary oscillator. In this example, the second cantilever flexure extends vertically upward so that the second cantilever has an unstable equilibrium at zero displacement. This helps provide the initial displacement of the second cantilever flexure necessary to achieve parametric resonance.

If the input vibrations driving the first oscillator have sufficient amplitude to achieve snap-through of the primary oscillator, or if stochastic resonance achieves snap-through of the first oscillator, the first oscillator will drive the subsidiary oscillator at the snap-through rate, regardless of the frequency of the input vibrations. If the snap-through rate is matched to a resonant frequency of the subsidiary oscillator so that Wₛₙₐₚ is substantially equal to 2 ω₀/n, where ω₀ is a resonant frequency of the subsidiary oscillator and n is a positive integer, then the subsidiary oscillator will parametrically resonate.

FIG. 3 shows a second embodiment of a VEH in accordance with the invention in which subsidiary oscillators are driven in direct resonance. The embodiment comprises a primary oscillator comprising a clamped-clamped beam 20, clamped at both ends to a frame 28. The primary oscillator comprises a centrally positioned mass 29 fixed to the clamped-clamped beam 20. The primary oscillator is bi-stable because the clamped-clamped beam is longer that the distance between its fixed ends so that there are two, bowed, stable equilibrium configurations for the clamped-clamped beam.

A first subsidiary oscillator comprising a first cantilever beam 22a is coupled to the primary oscillator by a rigid fixing to the mass 29. A second subsidiary oscillator comprising a second cantilever beam 22b is coupled to the primary oscillator by a rigid fixing to the mass 29. The first and second subsidiary oscillators are positioned above the primary oscillator such that the length of the subsidiary oscillators lie parallel with the length of the clamped-clamped beam 20. The first cantilever beam 22a has a proof mass 25 attached to its free end. The second cantilever beam 22b has a second proof mass 24 attached to its free end. Third and fourth subsidiary oscillators are positioned below the clamped-clamped beam in a similar fashion. The third subsidiary oscillator comprises a third cantilever beam 23a coupled to the primary oscillator by a rigid fixing to the mass 29. The fourth subsidiary oscillator comprises a fourth cantilever beam 23b coupled to the primary oscillator by a rigid fixing to the mass 29. The third cantilever beam 23a has a proof mass 27 attached to its free end. The fourth cantilever beam 23b has a second proof mass 26 attached to its free end. Piezoelectric transducers (not shown) are positioned on each of the cantilever beams between the mass 29 and the respective proof mass.

Ambient vibrations act on the VEH in a first direction shown by arrow 21. The ambient vibrations drive the primary oscillator in the first direction. Again snap-through of the clamped-clamped beam may be achieved if the input vibration has sufficient amplitude and/or if stochastic resonance occurs. The snap-through rate is independent of the frequency of the input vibrations. The motion of the clamped-clamped beam directly drives each of the subsidiary oscillators. If the snap-through rate is matched to a resonant frequency of a subsidiary oscillator so that ωₛₙₐₚ is substantially equal to a resonant frequency of a subsidiary oscillator, that subsidiary oscillator will resonate, providing amplification of the input vibrations. The first, second, third and fourth subsidiary oscillators may each have a substantially identical resonant frequency. Energy is harvested from the piezoelectric transducers that produce a voltage as they are placed under strain.

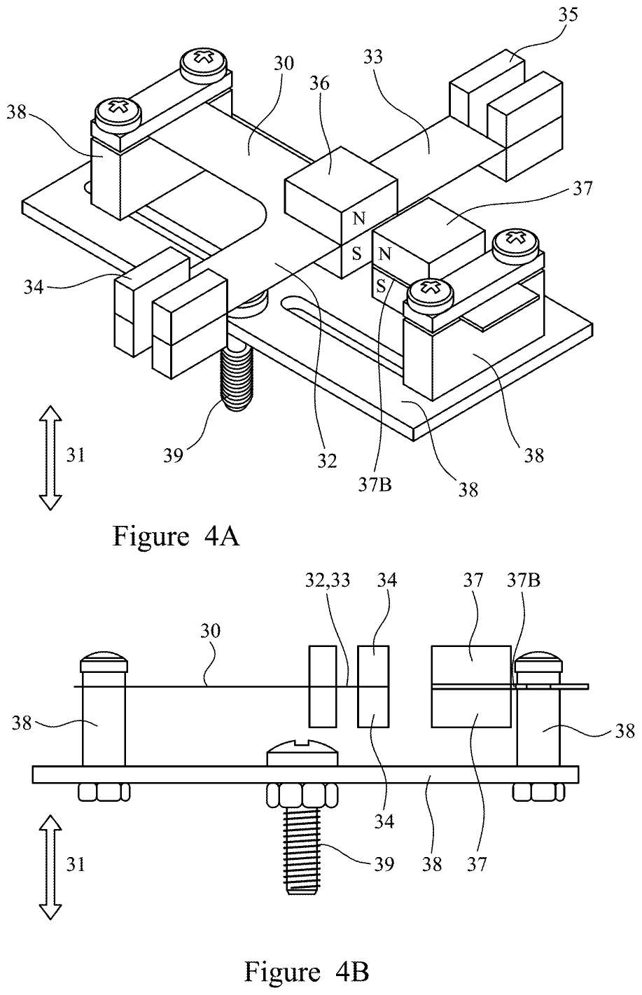

FIG. 4A shows a third embodiment of a VEH in accordance with the invention. The VEH comprises a primary oscillator, which comprises a resilient cantilever beam 30 fixed at one end to a frame 38. A first magnet 36 is attached to the free end of the cantilever beam 30. A second magnet 37 is attached to a rigid beam 37B which is attached to the frame 38. The first and second magnets are arranged in magnetic opposition such that the second magnet 37 repels the first magnet 36.

A first subsidiary oscillator and a second subsidiary oscillator extend from the free end of resilient cantilever beam 30. The first subsidiary oscillator comprises a first subsidiary cantilever beam 32 and a proof mass 34 fixed to a free end of the first subsidiary cantilever beam 32. The second subsidiary oscillator comprises a second subsidiary cantilever beam 33 and a proof mass 35 fixed to a free end of the second subsidiary cantilever beam 33. The resilient cantilever beam 30 and first and second subsidiary cantilever beams 32, 33 are integrally formed from a single, T-shaped piece of spring steel.

A fixing bolt 39 is provided on the base of the frame 38 to fix the base of the frame to an external vibrating structure.

Ambient vibrations in the first direction 31 act on the VEH. The primary oscillator vibrates in the first direction 31, perpendicular to the base of the frame. Due to repulsion between the magnets 36 and 37 the zero-displacement position (shown in FIG. 4A) is unstable and the primary oscillator is bi-stable. The oscillation of the primary oscillator directly drives subsidiary oscillators.

A power output can be extracted from transducers that damp the subsidiary oscillators. In this example proof masses 34 and 35 comprise permanent magnets arranged on either side of a slot. A fixed coil 304, 305 (fixed relative to the frame) is received in each slot, as illustrated in FIG. 4C but not shown in FIGS. 4A and 4B. As the subsidiary oscillators resonate the magnets 34, 35 move past the coils, resulting in a changing magnetic flux across each coil 304, 305. This induces a current in each coil, which is the output of the VEH. Output terminals 306, 307 are connected to each coil.

Snap-through of the primary oscillator may be achieved if the input vibration has sufficient amplitude and/or if stochastic resonance occurs. The snap-through rate is independent of the frequency of the input vibrations. The motion of the primary oscillator directly drives each of the subsidiary oscillators. If the snap-through rate is matched to a resonant frequency of a subsidiary oscillator so that ωₛₙₐₚ is substantially equal to a resonant frequency of a subsidiary oscillator, that subsidiary oscillator will resonate, providing amplification of the input vibrations.

It may possible to harvest energy even if snap-through is not achieved. If the primary oscillator is vibrating or even resonating, within one of the potential intra-wells, energy can be still be harvested by damping the primary oscillator and/or the subsidiary oscillators.

FIG. 4B shows a side view of the third embodiment illustrating that the primary cantilever beam 30 is in the same plane as the subsidiary cantilever beams 32 and 33 when in the zero-displacement position. The zero-displacement position, as shown in FIG. 4A is a position in which the primary oscillator (or bi-stable oscillator) is unstable because of repulsion between the magnets 36 and 37.

FIG. 4C shows a top view of the third embodiment illustrating the T-shape of the primary and subsidiary cantilever beams. The two subsidiary cantilever beams 32 and 33 have the same length as one another in this embodiment, however it is also possible to have different length subsidiary cantilever beams which may resonate at different frequencies. It is also possible to have further subsidiary oscillators coupled to the bi-stable oscillator, which could be parallel to the first and second subsidiary oscillators and may act as direct resonators, or perpendicular to the first and second subsidiary oscillators and may act as parametric resonators. As described above, a fixed coil 304, 305 is received in each slot. As the subsidiary oscillators resonate the magnets 34, 35 move past the coils, resulting in a changing magnetic flux across each coil 304, 305. This induces a current in each coil, which is the output of the VEH.

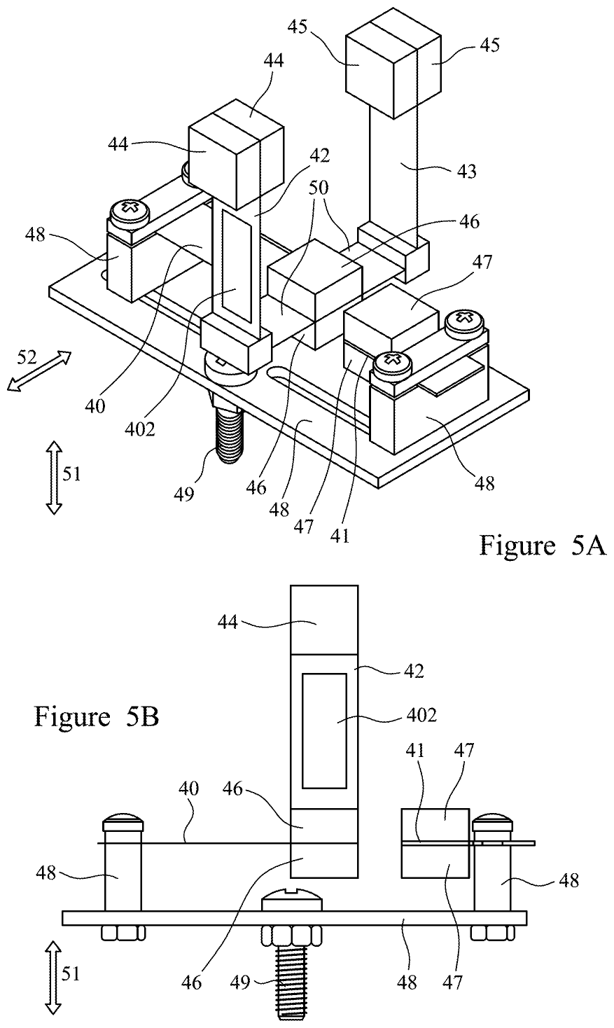

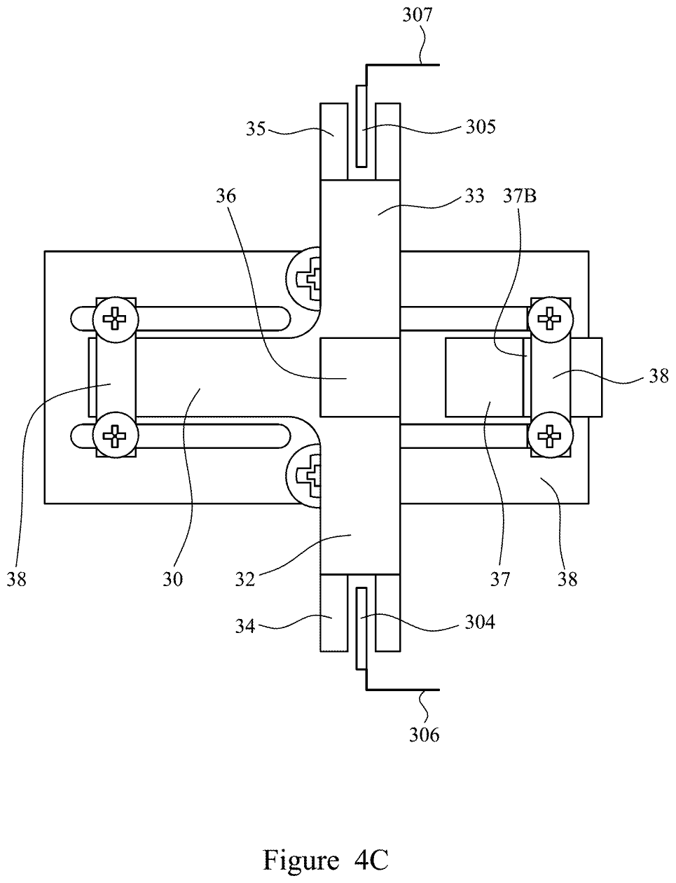

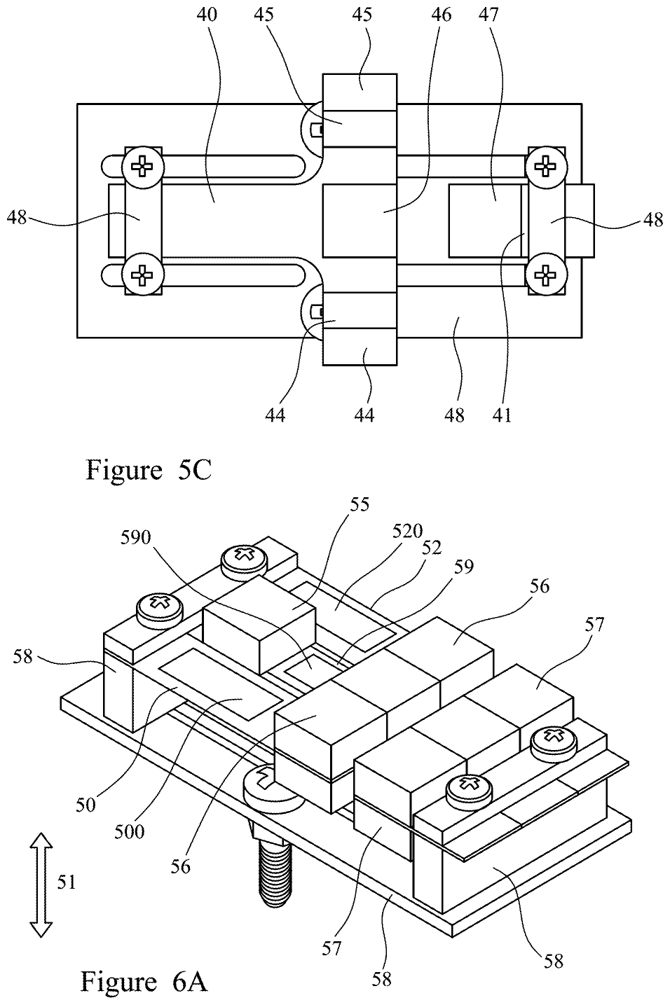

FIG. 5A shows a perspective view of a fourth embodiment of the invention. FIG. 5B shows a side view of the fourth embodiment of the invention. FIG. 5C shows a top view of the fourth embodiment. The embodiment comprises a primary oscillator comprising a primary cantilever beam 40 which is fixed at one end to a frame 48. A first magnet 46 is attached to the free end of the primary cantilever beam 40. A second magnet 47 is attached to a rigid coupling 41 which is attached to the frame 48 so that the first and second magnets are proximate to one another. The first and second magnets are arranged in magnetic opposition to one another so that they repel each other. This magnetic repulsion induces bi-stability in the primary cantilever beam, as previously described.

The primary oscillator is coupled to a first subsidiary oscillator and a second subsidiary oscillator by a coupling beam 50. The subsidiary oscillators comprise subsidiary cantilever beams 42 and 43 extending perpendicular to the primary cantilever beam 40, and parallel to an expected input ambient vibration. Proof masses 44 and 45 are fixed to the free ends of the first subsidiary cantilever beam and a second subsidiary cantilever beam. The frame 48 is attached to a vibrating structure by a fixing bolt 49.

The ambient vibrations are in a direction parallel to the subsidiary cantilever beams 42, 43, as indicated by arrow 51. These vibrations drive the bi-stable primary oscillator. Motion of the primary cantilever beam 40 perpendicular to the base of the frame 48 in a first direction 51 drives the subsidiary cantilever beams 42 and 43 parametrically. The subsidiary oscillators vibrate perpendicular to the vibration of the primary oscillator in a second direction 52. A parametric mode of operation can provide more efficient conversion of vibration energy into electrical energy.

In order to achieve parametric resonance in a subsidiary oscillator, the frequency of vibration of the primary oscillator must be matched to a resonant frequency of the subsidiary oscillator so that the frequency of vibration of the primary oscillator is equal to or nearly equal to 2 ω₀/n, where ω₀ is a resonant frequency of the subsidiary oscillator and n is a positive integer.

If the input vibrations driving the primary oscillator have sufficient amplitude to achieve snap-through of the primary oscillator, or if stochastic resonance achieves snap-through of the first oscillator, the first oscillator will drive the subsidiary oscillator at the snap-through rate, regardless of the frequency of the input vibrations. If the snap-through rate is matched to a resonant frequency of the subsidiary oscillator so that ωₛₙₐₚ is substantially equal to 2 ω₀/n, where ω₀ is a resonant frequency of the subsidiary oscillator and n is a positive integer, then the subsidiary oscillator will parametrically resonate.

A power output can be extracted by coupling transducers to the subsidiary oscillators. Piezoelectric transduction and/or electromagnetic transduction can be used. In this example, piezoelectric material 402 is fixed to each of the subsidiary cantilever beams 42, 43 (the piezoelectric material 402 is only visible on one of the subsidiary cantilever beams 42 in FIGS. 5A and 5B). As the beams deflect, the piezoelectric material is placed under strain, which generates a voltage across the piezoelectric material. The piezoelectric material may be connected to an output of the VEH and may be connected to an energy storage device, such as a battery or capacitor or directly to a component to be powered, such as a sensor.

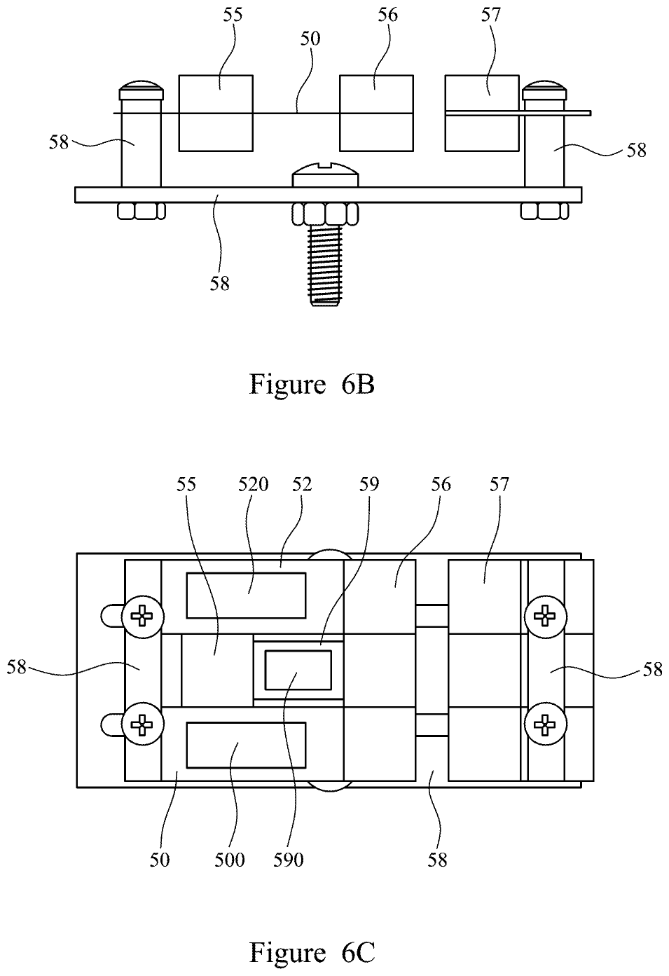

FIG. 6A shows a perspective view of a fifth embodiment of the invention. FIG. 6B shows a side view of the fifth embodiment of the invention. FIG. 6C shows a top view of the fifth embodiment. The embodiment comprises a primary oscillator comprising two primary cantilever beams 50, 52 which are fixed at one end to a frame 58. A first magnet 56 is attached to the free end of the primary cantilever beams 50, 52. A second magnet 57 is attached to a rigid coupling which is attached to the frame 58 so that the first and second magnets are proximate to one another. The first and second magnets are arranged in magnetic opposition to one another so that they repel each other. This magnetic repulsion induces bi-stability in the primary cantilever beams, as previously described.

The primary oscillators are coupled to a subsidiary oscillator. The subsidiary oscillator comprises a subsidiary cantilever beam 59 extending parallel to the primary cantilever beams 50, 52, and perpendicular to an expected input ambient vibration. Proof mass 55 is fixed to the free end of the subsidiary cantilever beam. The frame 58 is attached to a vibrating structure by a fixing bolt.

The ambient vibrations drive the bi-stable primary oscillator in a first direction 51. Motion of the primary cantilever beams 50, 52 perpendicular to the base of the frame 58 drives the subsidiary oscillator directly or parametrically, depending on the frequency of snap-through. The subsidiary oscillator vibrates parallel to the vibration of the primary oscillator.

In order to achieve parametric resonance in a subsidiary oscillator, the frequency of vibration of the primary oscillator must be matched to a resonant frequency of the subsidiary oscillator so that the frequency of vibration of the primary oscillator is equal to or nearly equal to 2 ω₀/n, where ω₀ is a resonant frequency of the subsidiary oscillator and n is a positive integer.

If the input vibrations driving the primary oscillator have sufficient amplitude to achieve snap-through of the primary oscillator, or if stochastic resonance achieves snap-through of the first oscillator, the first oscillator will drive the subsidiary oscillator at the snap-through rate, regardless of the frequency of the input vibrations. If the snap-through rate is matched to a resonant frequency of the subsidiary oscillator so that ωₛₙₐₚ is substantially equal to 2 ω₀/n, where ω₀ is a resonant frequency of the subsidiary oscillator and n is a positive integer, then the subsidiary oscillator will parametrically resonate.

A power output can be extracted by coupling transducers to the subsidiary oscillators. Piezoelectric transduction and/or electromagnetic transduction can be used. In this example, piezoelectric material layers 500, 520 are fixed to each of the subsidiary cantilever beams 50, 52 and piezoelectric material layer 590 is fixed to subsidiary cantilever beam 59. As the beams deflect, the piezoelectric material is placed under strain, which generates a voltage across the piezoelectric material. The piezoelectric material layers may be connected to an output of the VEH and may be connected to an energy storage device, such as a battery or capacitor or directly to a component to be powered, such as a sensor.

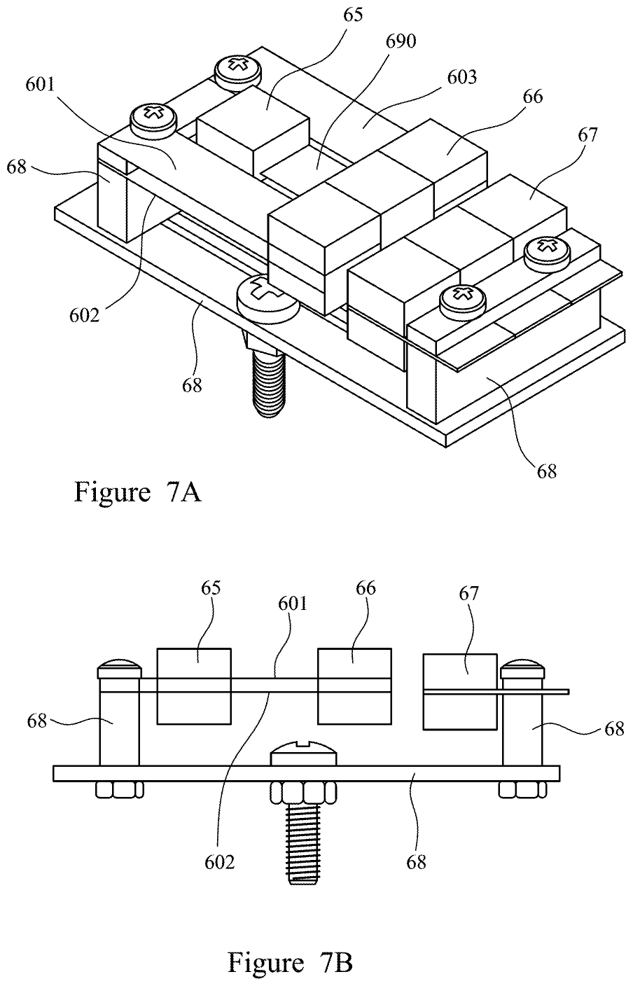

FIG. 7A is a schematic diagram of a sixth embodiment of a vibration energy harvester in accordance with the invention. FIG. 7B is a side view of the embodiment shown in FIG. 7A. The sixth embodiment is very similar to the fifth embodiment shown in FIGS. 6A, 6B and 6C. But in the sixth embodiment, each of the cantilever flexures of the sixth embodiment is replaced with a pair of identical cantilever flexures, spaced from one another in a direction of the input ambient vibrations. The use of a pair of spaced flexure elements in this way increases the resonant frequency of torsional modes of vibration, to a frequency higher than the band of frequencies covered by ambient vibrations. This effectively constrains the vibrational energy harvester from vibrating in undesirable torsional modes that would result in wear between components.

The sixth embodiment comprises a primary oscillator comprising two pairs of primary cantilever beams 601, 602, 603 (only the uppermost cantilever beam of a second pair of primary cantilever beams is visible in FIG. 7A) which are fixed at one end to a frame 68. A first magnet 66 is attached to the free end of the primary cantilever beams. A second magnet 67 is attached to a rigid coupling which is attached to the frame 68 so that the first and second magnets are proximate to one another. The first and second magnets are arranged in magnetic opposition to one another so that they repel each other. This magnetic repulsion induces bi-stability in the primary cantilever beams, as previously described.

The primary oscillators are coupled to a subsidiary oscillator. The subsidiary oscillator comprises a pair of subsidiary cantilever beams 690 (only the uppermost of which is visible in FIG. 7A) extending parallel to the pairs of primary cantilever beams 601, 602, 603 and perpendicular to an expected input ambient vibration. Proof mass 65 is fixed to the free end of the subsidiary cantilever beams 690. The frame 68 is attached to a vibrating structure by a fixing bolt.

The ambient vibrations drive the bi-stable primary oscillators in a first direction 51. Motion of the primary cantilever beams 601, 602, 603 perpendicular to the base of the frame 68 drives the subsidiary oscillator directly or parametrically in the same manner as described with reference to FIGS. 6A, 6B and 6C.

The dual cantilever structure comprising a pair of cantilever beams, may be used in place of all or only some of the single cantilever beams shown in the preceding embodiments. For example, it is possible to have only the primary oscillator comprise a dual cantilever structure and the subsidiary oscillator use a single cantilever beam. Equally it is possible to stack more than two cantilever beams to further increase torsional stiffness.

A power output can be extracted by coupling transducers to the subsidiary oscillators. Piezoelectric transduction and/or electromagnetic transduction can be used. The transducers are not shown in FIGS. 7A and 7B.

It should be clear that other embodiments not explicitly described which comprise a primary bi-stable oscillator and one or more subsidiary oscillators coupled to the bi-stable oscillator may be implemented to deliver both resonant amplification and broadband response. For example, subsidiary oscillators of differing sizes, or subsidiary oscillators whereby one is a direct resonator and one is a parametric resonator, or more than two subsidiary oscillators may all be possible alternatives.

It should also be clear that the use of two or more parallel flexures, spaced in a thickness direction, in a single oscillator structure, as shown in FIG. 7A, may be used in place in any of the single flexures shown in FIGS. 2 to 6, in order to reduce undesirable torsional modes of vibration.

1. An energy harvester for harvesting energy from broadband ambient vibrations having a particular average amplitude, comprising:
a bi-stable oscillator,
a subsidiary oscillator mechanically coupled to the bi-stable oscillator;
wherein the bi-stable oscillator has a snap-through frequency, ωₛₙₐₚ, as a result of the ambient vibrations, and wherein the subsidiary oscillator exhibits resonance when driven at a frequency of ωₛₙₐₚ; and
at least one transducer coupled either to the bi-stable oscillator or to the subsidiary oscillator.

2. An energy harvester according to claim 1, wherein the subsidiary oscillator is arranged to be driven in parametric resonance by oscillation of the bi-stable oscillator.

3. An energy harvester according to claim 1, wherein ωₛₙₐₚ is substantially equal to 2 ω₀/n, where ω₀ is a resonant frequency of the subsidiary oscillator and n is a positive integer.

4. An energy harvester according to claim 1, wherein the subsidiary oscillator is arranged to oscillate in a direction orthogonal to a direction of oscillation of the bi-stable oscillator.

5. An energy harvester according to claim 1, wherein the subsidiary oscillator is arranged to be driven in direct resonance by oscillation of the bi-stable oscillator.

6. An energy harvester according to claim 5, wherein ωₛₙₐₚ is substantially equal to ω₀, where ω₀ is a resonant frequency of the subsidiary oscillator.

7. An energy harvester according to claim 6, wherein 0.6ω₀<ωₛₙₐₚ<1.4ω₀.

8. An energy harvester according to claim 1, wherein the energy harvester comprises a frame to which the bi-stable oscillator is coupled.

9. An energy harvester according to claim 1, wherein a magnetic field is used to induce bi-stability in the bi-stable oscillator.

10. An energy harvester according to claim 1, wherein the bi-stable oscillator comprises a cantilever flexure or a membrane flexure.

11. An energy harvester according to claim 10, wherein the membrane flexure comprises a clamped-clamped beam.

12. An energy harvester according to claim 1, wherein the bi-stable oscillator comprises a pre-stressed resilient member.

13. An energy harvester according to claim 12, wherein the bi-stable oscillator is integrally formed with the subsidiary oscillator.

14. An energy harvester according to claim 12, wherein the bi-stable oscillator is mechanically fixed to the subsidiary oscillator.

15. An energy harvester according to claim 14, wherein the subsidiary oscillator comprises a proof mass attached to a resilient flexure.

16. An energy harvester according to claim 1, wherein the bi-stable oscillator comprises a proof mass attached to a resilient flexure.

17. An energy harvester according to claim 1, wherein the ambient vibrations comprise a periodic vibration and a broadband vibration wherein the bi-stable oscillator is driven in stochastic resonance by the ambient vibrations.

18. An energy harvester according to claim 17, wherein the energy harvester is configured to have a snap-through rate as a result of the ambient vibrations substantially equal to twice the frequency of the periodic vibration.

19. An energy harvester according to claim 1, comprising a plurality of subsidiary oscillators mechanically coupled to the bi-stable oscillator.

20. A method for harvesting energy from ambient vibrations using broadband resonance of a vibration energy harvester comprising a bi-stable oscillator mechanically coupled to a subsidiary oscillator, the method comprising:
exposing the bi-stable oscillator to ambient vibrations in order to excite the bi-stable oscillator with a snap through frequency, ωₛₙₐₚ, such that ωₛₙₐₚ is related to a resonant frequency of the bi-stable oscillator so that the subsidiary oscillator resonates when driven at a frequency of ωₛₙₐₚ, and
extracting a power output by damping either the bi-stable oscillator or the subsidiary oscillator, or damping both the bi-stable oscillator and the subsidiary oscillator.

21. A method according to claim 20, wherein ωₛₙₐₚ is substantially equal to 2ω₀/n where ω₀ is a resonant frequency of the bi-stable oscillator and n is a positive integer.

22. A method according to claim 20, wherein the ambient vibrations include at least one periodic vibration and wherein the bi-stable oscillator is driven in stochastic resonance.

23. A method according to claim 20, wherein the bi-stable oscillator is excited by ambient vibrations to drive the subsidiary oscillator in direct resonance.

24. A method according to claim 20, wherein the bi-stable oscillator is excited by ambient vibrations to drive the subsidiary oscillator in parametric resonance.

25. A method according to any one of claim 20, wherein the step of extracting a power output comprises piezoelectrically damping the subsidiary oscillator and/or electromagnetically damping the subsidiary oscillator.
